(19) United States
(12) Patent Application Publication
(10) Pub. No.: US 2008/0023736 A1
(43) Pub. Date: Jan. 31, 2008

(54) Semiconductor Device and Method for Manufacturing the Same

(76) Inventor: Yung Pil Kim, Echeon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/828,688

(22) Filed: Jul. 26, 2007

(30) Foreign Application Priority Data
Jul. 27, 2006 (KR) 10-2006-0071049

(51) Int. Cl. H01L 31/113; H01L 21/00

(52) U.S. Cl. 257/292; 438/57; 257/E27.132

(57) ABSTRACT

An overlay key for a semiconductor device is provided. The semiconductor device can include a first insulating layer having a trench serving as an outer key; and a metal layer formed on the first insulating layer including in the trench of the outer key. Here, an inner key region of the metal layer is etched. The metal layer formed in the trench of the outer key can be formed on a residual first metal remaining, for example, from a via plug formation process to inhibit contact between the remaining first metal in the trench of the outer key and a second insulating layer formed on the metal layer.

### CROSS-REFERENCE TO RELATED APPLICATION

The present application claims priority under 35 U.S.C. §119 of Korean Patent Application No. 10-2006-0071049, filed Jul. 27, 2005, which is hereby incorporated by reference in its entirety.

### BACKGROUND

Overlay keys are used during a fabricating process for semiconductor devices to help with aligning multiple masks, and are used to monitor layer-to-layer alignment in multi-layer device structures. In the fabricating process, device components are formed by repeatedly performing deposition and patterning processes.

An overlay key is typically formed on a scribe lane of a wafer where no chip is to be formed. A tool for measuring an alignment state of the overlay key is used to measure overlay accuracy, the degree of misalignment between consecutive layers.

However, a lifting phenomenon of an insulating layer may occur at the overlay key during metal interconnection formation in the fabricating process, so particles of the insulating layer are transferred to other regions, degrading reliability of products.

In the case of semiconductor devices, especially, in the case of products such as CMOS image sensors for obtaining high-quality images, the image may have fatal defects when the lifting of the insulating layer occurs.

### BRIEF SUMMARY

Embodiments of the present invention provide a semiconductor device capable of preventing lifting phenomenon at an overlay key and a method for manufacturing the same.

The semiconductor device according to an embodiment includes a first insulating layer including a trench serving as an outer key; and a metal layer formed on the first insulating layer including in the trench of the outer key, wherein an inner key region is positioned as an etched region of the metal layer.

A method for manufacturing a semiconductor device according to an embodiment can include: forming a first insulating layer on a scribe lane of a substrate; forming a trench serving as an outer key by selectively etching the first insulating layer; depositing a metal layer on the first insulating layer including the trench using a second metal; forming a photoresist film on the metal layer; and forming an inner key by patterning the photoresist film to expose an inner key region of the metal layer.

### BRIEF DESCRIPTION OF THE DRAWINGS

FIG. 1 is a plan view of an example overlay key.

FIG. 2 is a sectional view of a semiconductor device according to an embodiment; and

FIGS. 3-7 are sectional views showing the manufacturing procedure for a semiconductor device according to an embodiment.

### DETAILED DESCRIPTION

Hereinafter, a semiconductor device and a method for manufacturing the same according to embodiments of the present invention will be explained with reference to accompanying drawings.

In the following description, the expression “formed on/under each layer” may include the meaning of both “formed directly on/under each layer” and “formed indirectly on/under each layer by interposing other layer therebetween.”

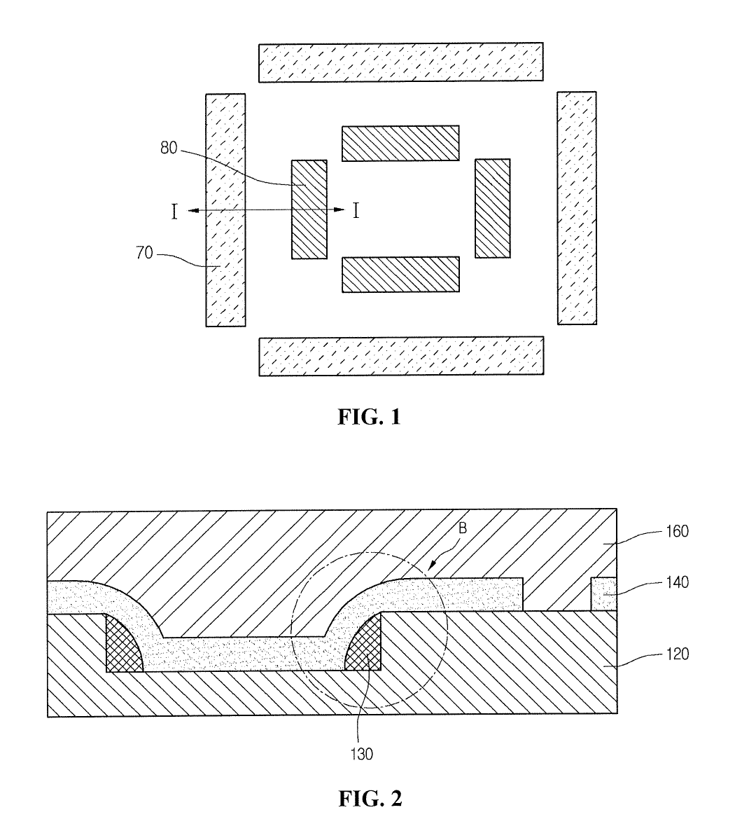

A semiconductor device according to an embodiment will be described with reference to FIGS. 1 and 2.

As illustrated in FIG. 1, an overlay key can include an outer key 70 and an inner key 80.

FIG. 2 shows an embodiment of a semiconductor device at a scribe region including a first insulating layer 120 including an outer key region 70, a remaining first metal 130, a metal layer 140 including an inner key region 80, and a second insulating layer 160.

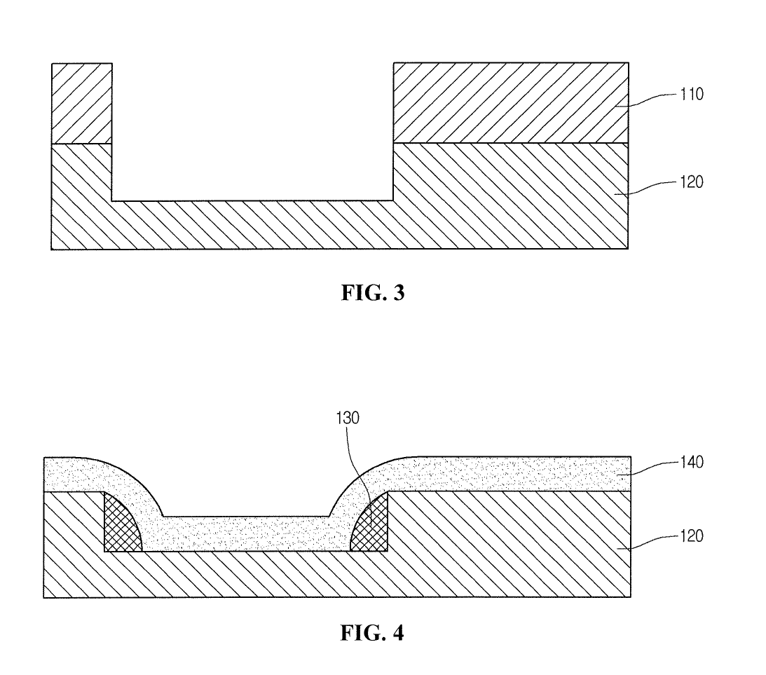

The outer key region 70 in the first insulating layer 120 can be formed by etching the first insulating layer 120 using a first photoresist film 110 (see FIG. 3) to form a trench. In an embodiment, the trench can be formed during a process to form via holes for a semiconductor device.

During a process of forming via plugs, a first metal is deposited to fill via holes (not shown) of the semiconductor device, and is removed from regions where the first metal is not required. The first metal can include, for example, W, Al, Cu, Ti, or TiN.

In particular, in the via plug formation process, the first metal fills in the trench of the outer key region 70 and the via holes (not shown). Then, the first metal is subject to a planarization process, for example, a CMP process in such a manner that the first metal is filled in the via holes, but removed from surface regions of the remaining areas of the substrate. The CMP process leaves the first metal in the trench of the outer key 70, so a separate step can be performed to remove the first metal from the trench. At this time, the first metal cannot be completely removed due to the step difference in the sidewall of the trench of the outer key 70, so that a part of the first metal may remain. This remaining first metal 130 can cause lifting of a subsequently formed insulating layer due to cracking from stress between the layers.

After the via plug formation process, a metal interconnection (not shown) can be formed by depositing a metal layer 140 of a second metal on the first insulating layer 120 including in the trench of the outer key 70. An inner key region 80 of the second metal layer 140 can be etched such that the first insulating layer 120 can be partially exposed through the second metal layer 140.

The second metal includes, for example, Al, W, Cu, Ti, TiN, W, WN, TiW, or TaW.

In a further embodiment, a barrier metal layer can be formed between the insulating layer 120 and the second metal layer 140. The barrier metal layer is formed at a lower portion of the metal interconnection 140 and can include, for example, Ti/TiN, TiW, or TiSi₂.

The second insulating layer 160 is then deposited on the metal layer 140 and the exposed first insulating layer 120.

As described above, the semiconductor device according to an embodiment can inhibit the lifting of the insulating layer, which is a problem of a related art, by surrounding the outer key 70 formed in the previous process using the metal layer when forming the inner key 80 of the overlay key, thereby improving reliability of the semiconductor device.

In addition, according to an embodiment, a lifting phenomenon that causes fatal defect to the image characteristics can be inhibited, so that the image characteristics of a CMOS image sensor can be remarkably improved.

Hereinafter, a method for manufacturing a semiconductor device according to an embodiment will be described in detail with reference to accompanying drawings.

As shown in FIG. 3, a first insulating layer 120 can be formed on the scribe lane of the substrate (not shown). In one embodiment, a planarization process for the first interlayer dielectric layer can be performed, for example, a CMP process.

Then, the first insulating layer 120 can be etched using the first photoresist film 110 as an etch mask, thereby forming the trench that serves as the outer key 70.

A first metal can be filled in via holes (not shown) to form via plugs (not shown) for the semiconductor device. The first metal is also formed in the trench of the outer key region 70. The first metal includes, for example, W, Al, Cu, Ti, or TiN.

According to an embodiment, the first metal is subject to a planarization process, for example, a CMP process after the first metal has been filled in the trench and via holes (not shown) in such a manner that the first metal can be exclusively filled in the via holes (not shown) of the semiconductor device and the trench of the outer key region 70. Then, the first metal filled in the outer key region 70 is removed. At this time, as illustrated in FIG. 4, the first metal cannot be completely removed due to the step difference in the sidewall of the trench, so that a part of the first metal 130 may remain.

As shown in FIG. 4, a metal layer 140 can be deposited using a second metal on the first insulating layer including the remaining first metal 130 during a process of forming a metal interconnection. The second metal can be deposited using, for example, Al, W, Cu, Ti, TiN, W, WN, TiW, or TaW.

The method for manufacturing a semiconductor device can further include forming a barrier metal layer before depositing the second metal. The barrier metal layer can be formed at a lower portion of the metal interconnection 140 using, for example, Ti/TiN, TiW, or TiSi₂.

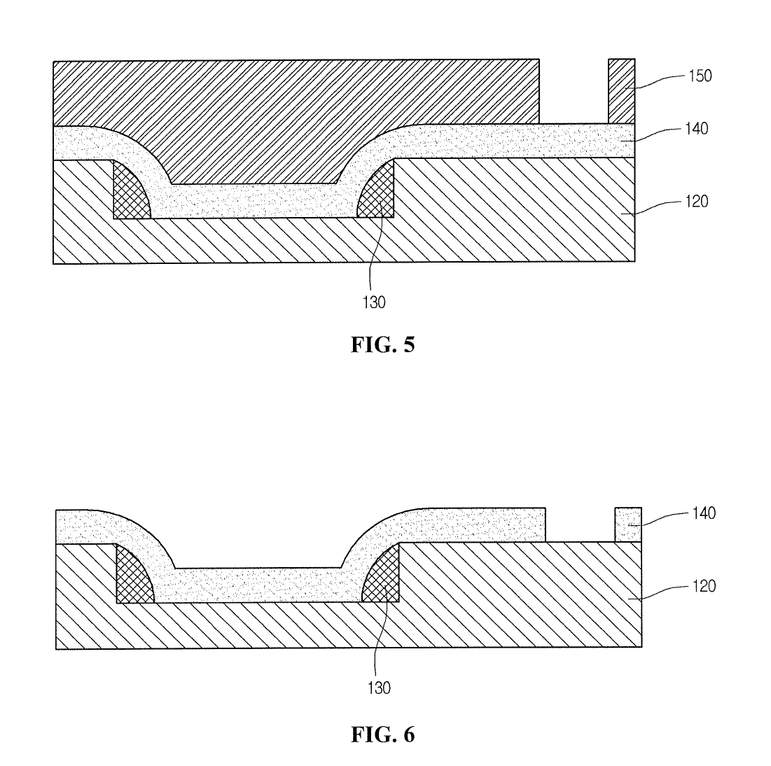

Then, as shown in FIG. 5, a second photoresist film 150 can be formed on the metal layer 140, and the second photoresist film 150 is patterned such that an inner key 80 can be formed. The portion of the second photoresist film 150 corresponding to the inner key 80 can be removed.

In detail, after a photo process has been performed, the inner key region 80 of the second photoresist film 150 is removed. Here, the alignment state is measured based on the step difference in the first insulating layer 120 of the outer key 70, which has been formed in the previous process, and the step difference in the second photoresist film 150 of the inner key 80.

In particular, different from the related art, the second photoresist film 150 is coated on the whole area of the resultant structure shown in FIG. 4, and then the inner key region 80 of the second photoresist film 150 is removed.

In forming the outer key 70 and the inner key 80, mask polarity of the first mask (not shown) for the portion of the first photoresist film 110 where the outer key 70 is formed later and mask polarity of the second mask (not shown) for the portion of the second photoresist film 150 where the inner key 80 is formed later are allowed to have white polarity, thereby removing the photoresist film.

This is possible when the first and second photoresist films 110 and 150 are positive photoresist films. The white polarity of the mask signifies that the mask pattern is formed to allow light to pass through the portions of the mask corresponding to the outer key 70 and the inner key 80.

If the first and second photoresist films 110 and 150 are negative photoresist films, the first and second masks may have dark polarity. The dark polarity of the mask signifies that the mask pattern is formed such that light cannot pass through the portions of the mask corresponding to the outer key 70 and the inner key 80.

Then, referring to FIG. 6, the portion of the metal layer 140 corresponding to the inner key 80 is etched using the second photoresist film 150 as an etch mask, thereby exposing a part of the first insulating layer.

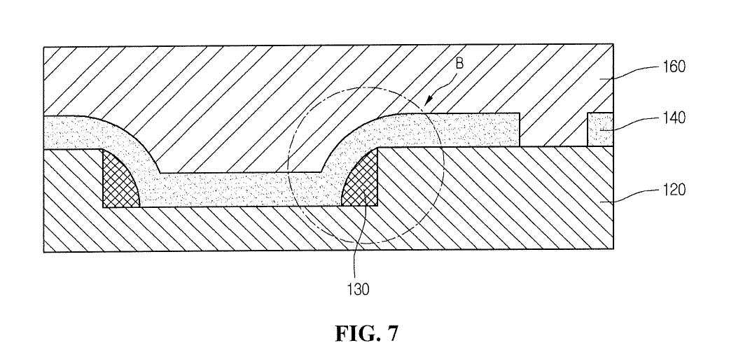

After that, as shown in FIG. 7, the second insulating layer 160 is deposited on the metal layer 140 and the exposed first insulating layer 120.

As described in the above embodiment, since the metal layer 140 surrounds any remaining first metal 130, the second insulating layer 160 does not make contact with the remaining first metal 130 when the second insulating layer 160 is deposited, so that the contact fault can be inhibited from occurring.

Thus, the lifting phenomenon of the second insulating layer 160 can be inhibited.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first insulating layer including a trench serving as an outer key; and
a metal layer formed on the first insulating layer including the trench, wherein the metal layer is etched at an inner key region.

2. The semiconductor device according to claim 1, further comprising a second insulating layer formed on the metal layer.

3. The semiconductor device according to claim 1, wherein the semiconductor device comprises a CMOS image sensor.

4. The semiconductor device according to claim 1, wherein the metal layer includes at least one selected from the group consisting of Al, W, Cu, Ti, TiN, W, W, TiW, and TaW.

5. The semiconductor device according to claim 1, wherein the metal layer formed on the trench surrounds the outer key.

6. The semiconductor device according to claim 1, wherein the metal layer is formed in the trench on a first metal remaining in the trench after a removal process of the first metal, wherein the first metal includes at least one selected from the group consisting of W, Al, Cu, Ti, and TiN.

7. The semiconductor device according to claim 6, further comprising a second insulating layer formed on the metal layer, wherein the second insulating layer does not make contact with the remaining first metal.

8. The semiconductor device according to claim 6, wherein the remaining first metal remains on a corner of the trench.

9. The semiconductor device according to claim 6, wherein the metal interconnection surrounds the remaining first metal.

10. The semiconductor device according to claim 1, wherein the metal layer is etched at the inner key region to expose a part of the first insulating layer.

11. A method for manufacturing a semiconductor device, the method comprising:
forming a first insulating layer on a scribe area of a substrate;
forming a trench serving as an outer key by selectively etching the first insulating layer using a patterned first photoresist film;
depositing a metal layer on the first insulating layer including the trench using a second metal;
forming a second photoresist film on the metal layer; and
forming an inner key by patterning the second photoresist film to expose the metal layer at an inner key region.

12. The method according to claim 11, further comprising the steps of:
exposing a part of the first insulating layer by etching the inner key region of the metal interconnection using the patterned second photoresist film as an etch mask; and
depositing a second insulating layer on the metal layer and the exposed first insulating layer.

13. The method according to claim 11, wherein mask polarity for a portion of the first photoresist film comprising the outer key is identical to mask polarity of a second mask for a portion of the second photoresist film comprising the inner key.

14. The method according to claim 13, wherein the first and second photoresist films comprise positive photoresist films, wherein mask polarity of the first and second masks is white polarity.

15. The method according to claim 11, wherein the semiconductor device comprises a CMOS image sensor.

16. The method according to claim 11, further comprising:
depositing a first metal on the substrate including in the trench; and
performing a removal process of the first metal formed in the trench, wherein residual first metal remains in the trench after the removal process,
wherein depositing the metal layer on the first insulating layer including the trench comprises:
depositing the metal layer on the first metal remaining in the trench.

17. The method according to claim 16, further comprising forming a second insulating layer the metal layer, wherein the second insulating layer does not make contact with the first metal remaining in the trench.

18. The method according to claim 16, wherein the first metal includes at least one selected from the group consisting of W, Al, Cu, Ti, and TiN.

19. The method according to claim 11, wherein the second metal includes at least one selected from the group consisting of Al, W, Cu, Ti, TiN, W, WN, TiW, and TaW.

20. The method according to claim 11, wherein the metal layer deposited on the trench surrounds the outer key.
